(19) United States
(12) Patent Application Publication
(10) Pub. No.: US 2021/0327987 A1
(43) Pub. Date: Oct. 21, 2021

(54) DISPLAY SUBSTRATE, METHOD FOR MANUFACTURING THE SAME, DISPLAY DEVICE

(71) Applicant: BOE TECHNOLOGY GROUP CO., LTD., Beijing (CN)

(72) Inventors: Jingang Fang, Beijing (CN); Jun Cheng, Beijing (CN); Ce Zhao, Beijing (CN); Luke Ding, Beijing (CN); Ning Liu, Beijing (CN)

(21) Appl. No.: 16/605,782

(22) PCT Filed: May 6, 2019
(86) PCT No.: PCT/CN2019/085690

§ 371 Date: Oct. 16, 2019

(30) Foreign Application Priority Data
May 9, 2018 (CN) 201810436886.2

(51) Int. Cl. H01L 27/32; H01L 51/52; H01L 51/56

(52) U.S. Cl. CPC H01L 27/3265; H01L 27/3276; H01L 27/322; H01L 2227/323; H01L 51/56; H01L 27/3272; H01L 51/5218

(57) ABSTRACT

A display substrate, a method for manufacturing the same, and a display device are provided. The display substrate includes: a base substrate, and a conductive layer and a passivation layer which are stacked on the base substrate. The display substrate has a peripheral region and a capacitor region, the conductive layer is located in the peripheral region, the conductive layer is used for electrically connecting with an external driving circuit in the display device, a thickness of a part of the passivation layer in the capacitor region is less than a thickness of a part of the passivation layer in the peripheral region, and the capacitor region is provided with a capacitor that charges a pixel unit in the display substrate.

### CROSS-REFERENCE TO RELATED APPLICATION(S)

This application is a Section 371 National Stage Application of International Application No. PCT/CN2019/085690, filed on May 6, 2019, which in turn claims the benefit of Chinese Patent Application No. 201810436886.2 filed on May 9, 2018 and entitled “DISPLAY SUBSTRATE, METHOD FOR MANUFACTURING THE SAME, DISPLAY DEVICE” in the National Intellectual Property Administration of China, the whole disclosure of which is incorporated herein by reference.

### TECHNICAL FIELD

The present disclosure relates to the field of display technologies, and in particular, to a display substrate, a method for manufacturing the same, and a display device.

### BACKGROUND

After finishing the manufacturing of a display substrate, signal lines on the display substrate need to be bonded to an external driving circuit. A bonding process is usually performed by pressing a signal line in a peripheral region of the display substrate with the external driving circuit so as to electrically connect the signal lines and the driving circuit.

### SUMMARY

The present disclosure provides a display substrate, a method of manufacturing the same, and a display device. The technical solution is as follows:

In one aspect, some embodiments of the present disclosure provide a display substrate comprising: a base substrate, and a conductive layer and a passivation layer which are stacked on the base substrate; the display substrate has a peripheral region and a capacitor region, the conductive layer is located in the peripheral region, and the conductive layer is used for electrically connecting with an external driving circuit, a thickness of a part of the passivation layer in the capacitor region is less than a thickness of a part of the passivation layer in the peripheral region; wherein the capacitor region is provided with a capacitor that charges a pixel unit in the display substrate.

Optionally, the thickness of the part of the passivation layer in the peripheral region is greater than or equal to a reference thickness threshold, and the thickness of the part of the passivation layer in the capacitor region is less than the reference thickness threshold, a passivation layer having a thickness of the reference thickness threshold is capable of withstanding a pressing force during a process of bonding the display substrate and the external driving circuit.

Optionally, the thickness of the part of the passivation layer in the capacitor region is half of the thickness of the part of the passivation layer in the peripheral region.

Optionally, the thickness of the part of the passivation layer in the peripheral region is in a range of [600 nm, 1000 nm], and the thickness of the part of the passivation layer in the capacitor region is in a range of [300 nm, 500 nm].

Optionally, an orthographic projection of the passivation layer on the base substrate substantially covers the base substrate, the thickness of the part of the passivation layer in the capacitor region is less than a thickness of a part of the passivation layer in other regions than the capacitor region.

Optionally, the passivation layer has the same thickness in the other regions.

Optionally, the display substrate further comprising: a thin film transistor between the base substrate and the passivation layer, wherein the thin film transistor is located in a display region which is surrounded by the peripheral region, and the capacitor region is located in the display region; wherein the thin film transistor comprises a source electrode, and the conductive layer is electrically connected to the source electrode.

Optionally, the display substrate further comprising: a thin film transistor between the base substrate and the passivation layer, wherein the thin film transistor is located in a display region which is surrounded by the peripheral region, and the capacitor region is located in the display region; wherein the thin film transistor comprises a gate electrode, and the conductive layer is electrically connected to the gate electrode.

Optionally, the thin film transistor is a thin film transistor with a top gate structure; wherein the display substrate further comprises: a light shielding layer between the base substrate and the thin film transistor, the thin film transistor comprises an active layer, an orthographic projection of the light shielding layer on the base substrate covers an orthographic projection of the active layer on the base substrate.

Optionally, the thin film transistor is a thin film transistor with a bottom gate structure; wherein the thin film transistor comprises a gate electrode and an active layer, and an orthographic projection of the gate electrode on the base substrate covers an orthographic projection of the active layer on the base substrate.

Optionally, the display substrate further comprising: a first capacitor electrode on a side of the passivation layer adjacent to the base substrate; and a second capacitor electrode on a side of the passivation layer away from the base substrate, wherein the first capacitor electrode and the second capacitor electrode are both located in the capacitor region, and the capacitor comprises the first capacitor electrode and the second capacitor electrode.

Optionally, the display substrate further comprising: a leading wire layer, wherein the leading wire layer is electrically connected to the conductive layer through a passivation-layer via hole penetrating the passivation layer.

Optionally, the passivation layer is made of one of polysiloxane and polysilazane.

Optionally, the display substrate has a display region surrounded by the peripheral region, the display region comprises the capacitor region, and the display substrate further comprises: a light shielding layer, a thin film transistor with a top gate structure, a first capacitor electrode, a planarization layer, an electrode layer, a light-emitting layer, a cathode layer, and a color filter layer) which are disposed on the base substrate; the light shielding layer and the thin film transistor are located in the display region, and an orthographic projection of the light shielding layer on the base substrate covers an orthographic projection of an active layer in the thin film transistor on the base substrate; the electrode layer comprises a second capacitor electrode, the first capacitor electrode and the second capacitor electrode are located in the capacitor region, the capacitor comprises the first capacitor electrode and the second capacitor electrode; the conductive layer is further used for electrically connecting with one of a source electrode and a gate electrode of the thin film transistor; an orthographic projection of the passivation layer on the base substrate substantially covers the base substrate, and the thickness of the part of the passivation layer in the capacitor region is equal to half of a thickness of a part of the passivation layer in other regions than the capacitor region, and the passivation layer has the same thickness in the other regions, the passivation layer is made of one of polysiloxane and polysilazane; the electrode layer further comprises a reflective anode layer, and a leading wire layer located in the peripheral region, the leading wire layer is electrically connected to the conductive layer through a passivation-layer via hole penetrating the passivation layer, and the reflective anode layer is electrically connected to the source electrode through a via hole penetrating both the planarization layer and the passivation layer.

Optionally, the capacitor region is located in a display region surrounded by the peripheral region, and the display substrate further comprises: a thin film transistor with a bottom gate structure, a first capacitor electrode, a color filter layer, a planarization layer, an electrode layer, a light-emitting layer, and a reflective cathode layer which are disposed on the base substrate; the thin film transistor is located in the display region, and an orthographic projection of a gate electrode of the thin film transistor on the base substrate covers an orthographic projection of an active layer of the thin film transistor on the base substrate; the electrode layer comprises a second capacitor electrode, the first capacitor electrode and the second capacitor electrode are located in the capacitor region, the capacitor comprises the first capacitor electrode and the second capacitor electrode; the conductive layer is further used for electrically connecting with one of a source electrode and the gate electrode of the thin film transistor; an orthographic projection of the passivation layer on the base substrate substantially covers the base substrate, and the thickness of the part of the passivation layer in the capacitor region is equal to half of a thickness of a part of the passivation layer in other regions than the capacitor region, and the passivation layer has the same thickness in the other regions, the passivation layer is made of one of polysiloxane and polysilazane; the electrode layer further comprises an anode layer and a leading wire layer located in a peripheral region, the leading wire layer is electrically connected to the conductive layer through a passivation-layer via hole penetrating the passivation layer, and the anode layer is electrically connected to the source electrode through a via hole penetrating both the planarization layer and the passivation layer.

In another aspect, some embodiments of the present disclosure provide a method for manufacturing a display substrate, the method comprising: defining a peripheral region and a capacitor region on a side of a base substrate; forming a conductive layer in the peripheral region on the side of the base substrate, the conductive layer being used for electrically connecting with an external driving circuit; forming a passivation layer on the base substrate on which the conductive layer is formed, a thickness of a part of the passivation layer in the capacitor region being less than a thickness of a part of the passivation layer in the peripheral region; wherein the capacitor region is used to form a capacitor that charges a pixel unit in the display substrate.

Optionally, the forming the passivation layer on the base substrate on which the conductive layer is formed comprises: forming a passivation film layer on the base substrate on which the conductive layer is formed; exposing the passivation film layer with a halftone mask, wherein an orthographic projection of a half-exposure region of the halftone mask on the base substrate at least covers an orthographic projection of the capacitor region on the base substrate during a exposure process; and developing the exposed passivation film layer to obtain the passivation layer.

Optionally, a passivation-layer via hole penetrating the passivation layer is provided in the passivation layer; in a case where a material forming the passivation film layer is a positive photosensitive material, a region of the halftone mask except the half-exposure region comprises an opaque region and at least one light transmissive region, and an orthographic projection of the at least one light transmissive region on the base substrate coincides with an orthographic projection of the passivation-layer via hole on the base substrate; or in a case where a material forming the passivation film layer is a negative photosensitive material, a region of the halftone mask except the half-exposure region comprises a light transmissive region and at least one opaque region, and an orthographic projection of the at least one opaque region on the base substrate coincides with an orthographic projection of the passivation-layer via hole on the base substrate.

Optionally, prior to forming the passivation layer, the method further comprising: forming a thin film transistor in a display region surrounded by the peripheral region on the side of the base substrate, the capacitor region being located in the display region; and forming a first capacitor electrode of the capacitor in the capacitor region on the side of the base substrate, wherein the conductive layer and the first capacitor electrode satisfy any one of the following: the conductive layer and the first capacitor electrode are formed by one same patterning process as a source electrode and a drain electrode of the thin film transistor; or the conductive layer and the first capacitor electrode are formed by one same patterning process as a gate electrode of the thin film transistor.

In another aspect, some embodiments of the present disclosure provide a display device comprising: the display substrate according to the above aspect.

### BRIEF DESCRIPTION OF THE DRAWINGS

In order to more clearly illustrate technical solutions in the embodiments of the present disclosure, drawings used in the description of the embodiments will be briefly described below. Obviously, the drawings in the following description are only some embodiments of the present disclosure, for those skilled in the art, other drawings can be obtained according to the drawings without any creative work.

FIG. 1 is a schematic structural view of a display substrate according to some embodiments of the present disclosure;

FIG. 2 is a schematic structural view of another display substrate according to some embodiments of the present disclosure;

FIG. 3 is a schematic structural view of still another display substrate according to some embodiments of the present disclosure;

FIG. 4 is a schematic structural view of yet another display substrate according to some embodiments of the present disclosure;

FIG. 5 is a schematic structural view of a display substrate of a bottom emission OLED display device according to some embodiments of the present disclosure;

FIG. 6 is a schematic structural view of a display substrate of a top emission OLED display device according to some embodiments of the present disclosure;

FIG. 7 is a flow chart of a method for manufacturing a display substrate according to some embodiments of the present disclosure;

FIG. 8 is a flow chart of a method for manufacturing a passivation layer according to some embodiments of the present disclosure;

FIG. 9 is a flow chart of another method for manufacturing a display substrate according to some embodiments of the present disclosure; and

FIG. 10 is a waveform diagram of transmittance of a SOG material as a function of a light wavelength, according to some embodiments of the present disclosure.

### DETAILED DESCRIPTION OF THE EMBODIMENTS

In order to make the objects, technical solutions and advantages of the present disclosure clear, the embodiments of the present disclosure will be further described in detail below with reference to the accompanying drawings.

In the related art, a display substrate usually includes a passivation layer which is located in a peripheral region and a capacitor region of the display substrate, and the passivation layer has the same thickness in both of the two regions. In a bonding process, a force for pressing a signal line to an external driving circuit is usually applied onto a part of the passivation layer in the peripheral region. At this time, if a thickness of the passivation layer is relative small, the part of the passivation layer in the peripheral region may be broken, causing other layers on a side of the passivation layer close to a base substrate to be exposed to water and oxygen, thus the other layers (such as a signal line) are prone to corrosion under the action of water and oxygen, resulting in defects such as breakage. Since a part of the passivation layer in the capacitor region is also used as a dielectric layer of a storage capacitor, if the thickness of the passivation layer is relative large, the capacitance of the storage capacitor becomes small, which adversely affects the display effect of a display device including the display substrate. Therefore, the passivation layer may not meet the requirements of compressive property and capacitance at the same time.

FIG. 1 is a schematic structural view of a display substrate according to some embodiments of the present disclosure. As shown in FIG. 1, the display substrate has a peripheral region A1 and a capacitor region A2. The capacitor region A2 may be located in a display region of the base substrate 00 (also referred to as Active Area, which is abbreviated as AA), and the peripheral region A1 may be a region around the display region. The peripheral region A1 may include at least one of a bonding region and a fan-out region located around the display region.

The display substrate may include the base substrate 00, and a conductive layer 01 and a passivation layer 02 stacked on the base substrate 00.

The conductive layer 01 is located in the peripheral region A1 and is used for electrically connecting with a driving circuit in a display device including the display substrate (i.e., an external driving circuit). That is, after the bonding is achieved, the conductive layer is used for signal transmission between the driver circuit and elements in the display region.

Moreover, it can be seen from FIG. 1 that a thickness d1 of a part of the passivation layer 02 in the capacitor region A2 is less than a thickness d2 of a part of the passivation layer 02 in the peripheral region A1.

In summary, some embodiments of the present disclosure provide the display substrate including the conductive layer and the passivation layer which are stacked on the base substrate, and the thickness of the part of the passivation layer in the capacitor region is smaller than that of the part of the passivation layer in the periphery region. Compared with the related art, since the thickness of the part of the passivation layer in the peripheral region is relative large, the compressive property of the passivation layer in the peripheral region may be improved, and since the thickness of the part of the passivation layer in the capacitor region is relative small, the influence of the passivation layer on the capacitance of the storage capacitor may be reduced, and the display effect of the display device may be ensured. Therefore, the passivation layer may meet the requirements of both the compressive property and the capacitance as much as possible.

Further, as shown in FIG. 1, the display substrate may further include: a first capacitor electrode 03 and a second capacitor electrode 04 respectively located on both sides of the passivation layer 02. The first capacitor electrode 03 and the second capacitor electrode 04 are both located in the capacitor region A2, and the first capacitor electrode 03 and the second capacitor electrode 04 may constitute a storage capacitor in the display substrate. The storage capacitor may be used to maintain a voltage of a pixel electrode, that is, the storage capacitor composed of the first capacitor electrode 03 and the second capacitor electrode 04 are used to charge a pixel unit in the display substrate. For example, the first capacitor electrode 03 may be located on a side of the passivation layer 02 close to the base substrate 00, and the second capacitor electrode 04 may be located on a side of the passivation layer 02 away from the base substrate 00.

In some embodiments of the present disclosure, a material forming the passivation layer 02 may be a material that may be patterned by an exposure and development process. For example, the material forming the passivation layer 02 may be a photoresist or a resin material similar in performance to the photoresist.

In some embodiments, the material forming the passivation layer 02 may be polysiloxane or polysilazane. The polysiloxane material is a kind of polymer in which a repeating silicon-oxygen (Si—O) bond acts as a main chain and a silicon atom is directly connected with an organic group, the polysiloxane material having a high transmittance. The polysiloxane material may also be referred to as Silicon On Glass (abbreviated as SOG), which may be prepared by controlling a hydrolysis condensation reaction of a polymer containing Si—O bonds in an organic solvent by means of the sol-gel technique. The performance of SOG is similar to that of a fluid photoresist in a liquid state, and the SOG may exhibit similar properties to photoresist after being deposited. That is, the polysiloxane material may be patterned by an exposure and development process, so that the thickness of the part of the formed passivation layer in the capacitor region is less than that of the part of the formed passivation layer in the peripheral region.

Alternatively, the thickness of the part of the passivation layer 02 in the peripheral region may be equal to a reference thickness threshold, and the thickness of the part of the passivation layer 02 in the capacitor region is less than the reference thickness threshold. The passivation layer 02 having a thickness of a reference thickness threshold is capable of withstanding a pressing force during the bonding process. That is, when a signal line is pressed to the driving circuit to achieve electrical connection by a certain amount of pressing force, the pressing force does not cause damage to the passivation layer 02 having the thickness equal to the reference thickness threshold. For example, the thickness of the part of the passivation layer 02 in the peripheral region may be in a range of [600 nm, 1000 nm].

Correspondingly, the thickness of the part of the passivation layer 02 in the capacitor region may be a thickness that can satisfy the charging requirement of the pixel unit. That is, when the passivation layer 02 is also used as a dielectric layer of the storage capacitor, the capacitance of the storage capacitor determined by the thickness of the part of the passivation layer 02 in the capacitor region enables the pixel unit to be charged according to the display requirement without undercharge. In an implementation manner, the thickness of the part of the passivation layer 02 in the capacitor region is half of the thickness of the part of the passivation layer 02 in the peripheral region. Illustratively, the thickness of the part of the passivation layer 02 in the capacitor region may be in a range of [300 nm, 500 nm].

Moreover, an orthographic projection of the passivation layer 02 on the base substrate 00 may generally cover the base substrate 00 substantially. In this case, the thickness of the part of the passivation layer 02 in the capacitor region A2 may be smaller than a thickness of a part of the passivation layer 02 in other regions than the capacitor region A2. Further, the passivation layer 02 may have the same thickness in the other regions. In this case, when the passivation layer 02 is manufactured, only the part of the passivation layer 02 in the capacitor region A2 may be thinned to meet the performance requirements of the storage capacitor, while the thickness of the part the passivation layer in the other regions is kept to an original thickness to ensure that the passivation layer 02 may withstand a large pressure and maintain good water and oxygen barrier properties. For example, the thickness d1 of the part of the passivation layer 02 in the capacitor region A2 may be half of the thickness d2 of the part of the passivation layer 02 in other regions.

The passivation layer of the display substrate provided by the embodiments of the present disclosure is not prone to be broken during the bonding process or during the packaging process, so that other layers are prevented from being corroded due to the breakage of the passivation layer, thereby avoiding the occurrence of a dark line due to the breakage of the signal line in the display substrate. Moreover, the display substrate provided by the embodiments of the present disclosure can also avoid a short circuit between a source-drain electrode on one side of the passivation layer and an electrode on the other side of the passivation layer which is caused by other layers being corroded and then piercing the passivation layer. Therefore, the display substrate provided by the embodiments of the present disclosure may effectively improve the yield of the product without affecting the capacitance of the storage capacitor. At the same time, since the thickness of the part of the passivation layer 02 in the capacitor region may satisfy the charging requirement of the pixel unit, compared with a technique of increasing the capacitance by increasing an area of the storage capacitor, it is not necessary to increase the area of the storage capacitor, and the aperture ratio of the pixel unit can be ensured, further the pixel unit may achieve the same brightness without increasing the power consumption.

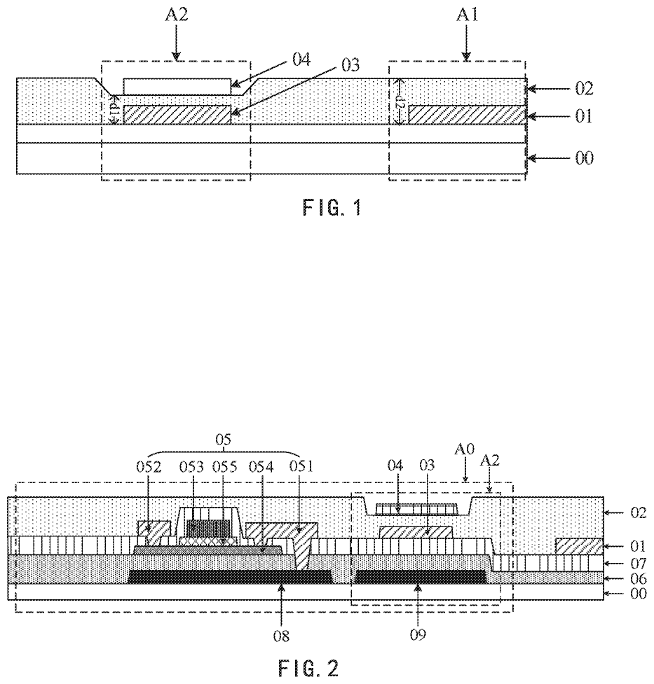

FIG. 2 is a schematic structural view of another display substrate according to some embodiments of the present disclosure. Referring to FIG. 2, the display substrate may further include:

a thin film transistor 05 disposed between the base substrate 00 and the passivation layer 02. The thin film transistor 05 is located in the display region A0, and the capacitor region A2 is located in the display region A0. The thin film transistor 05 is used to control whether or not to charge the capacitor electrodes.

As an alternative implementation manner, the conductive layer 01 and the first capacitor electrode 03 disposed on the side of the passivation layer 02 adjacent to the base substrate 00 may be formed by the same patterning process as a source electrode 051 and a drain electrode 052 of the thin film transistor 05. Correspondingly, the conductive layer 01 may be electrically connected to the source electrode 051, that is, the conductive layer 01 can be used as a source lead electrode in the display substrate, so that the source electrode 051 may be electrically connected to the driving circuit of the display device through the conductive layer 01.

As another alternative implementation manner, as shown in FIG. 3, the conductive layer 01 and the first capacitor electrode 03 disposed on the side of the passivation layer 02 adjacent to the base substrate 00 may be formed by the same patterning process as a gate electrode 053 of the thin film transistor 05. Correspondingly, the conductive layer 01 can be electrically connected to the gate electrode 053, that is, the conductive layer 01 may be a gate lead electrode in the display substrate, so that the gate electrode 053 may be electrically connected to the driving circuit in the display device through the conductive layer 01.

In the embodiments of the present disclosure, as shown in FIG. 2 and FIG. 3, a buffer layer 06 may be disposed on the base substrate 00, and the thin film transistor 05 may be disposed on a side of the buffer layer 06 away from the base substrate 00.

Optionally, the thin film transistor 05 disposed in the display substrate provided by the embodiments of the present disclosure may be a transistor with a top gate structure. As shown in FIG. 2 and FIG. 3, the thin film transistor 05 with the top gate structure may include an active layer 054, a gate insulating layer 055, and a gate electrode 053 which are sequentially located on the side of the buffer layer 06 away from the base substrate 00, an inter-layer dielectric (ILD) 07 on a side of the gate electrode 053 away from the base substrate 00, and a source electrode 051 and a drain electrode 052 on a side of the inter-layer dielectric 07 away from the base substrate 00. The source electrode 051 and the drain electrode 052 are respectively connected to the active layer 054 through contact via holes (not labeled in FIGS. 2 and 3). An orthographic projection of the inter-layer dielectric 07 on the base substrate substantially covers the base substrate 00.

Further, for the thin film transistor with the top gate structure, as shown in FIG. 2 and FIG. 3, the display substrate may further include: a light shielding layer 08 disposed on a side of the buffer layer 06 close to the base substrate 00. An orthographic projection of the light shielding layer 08 on the base substrate 00 covers an orthographic projection of the active layer 054 on the base substrate 00, that is, the orthographic projection of the active layer 054 on the base substrate 00 fall within the orthographic projection of the light shielding layer 08 on the base substrate 00 or coincides with the orthographic projection of the light shielding layer 08 on the base substrate 00. Further, in order to obtain a better shading effect, an orthographic projection of the thin film transistor 00 on the base substrate 00 may be located within the orthographic projection of the light shielding layer 08 on the base substrate 00.

The light shielding layer 08 may be an opaque film layer formed of an opaque material such as metal. In the thin film transistor with the top gate structure, the active layer is located on a side of the gate electrode close to the base substrate, and the active layer is sensitive to light. Therefore, by providing the light shielding layer 08, light may be prevented from being irradiated to the active layer to affect its performance. In addition, as shown in FIG. 3, the source electrode 051 may also be connected to the light shielding layer 08 through a via hole.

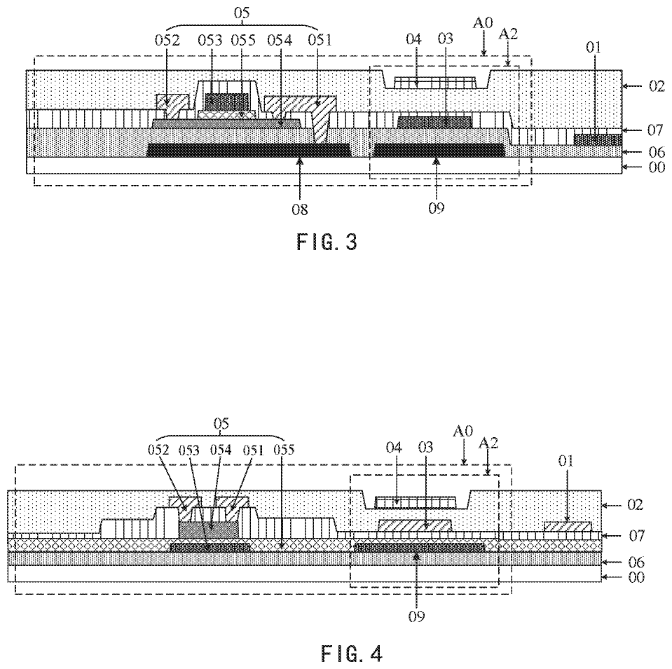

Optionally, the thin film transistor 05 disposed in the display substrate provided by the embodiments of the present disclosure may also be a transistor with a bottom gate structure. As shown in FIG. 4, the thin film transistor 05 with the bottom gate structure may include a gate electrode 053, a gate insulating layer 055, and an active layer 054 which are sequentially disposed on the side of the buffer layer 06 away from the base substrate 00, an inter-layer dielectric 07 on a side of the active layer 054 away from the base substrate 00, and, and a source electrode 051 and a drain electrode 052 on a side of the inter-layer dielectric 07 away from the base substrate 00. The source electrode 051 and the drain electrode 052 are respectively connected to the active layer 054 through contact via holes (not labeled in FIG. 4). An orthographic projection of the inter-layer dielectric 07 on the base substrate substantially covers the base substrate 00.

For the thin film transistor 05 with the bottom gate structure, the gate electrode 053 is provided on a side of the active layer 054 close to the base substrate 00, and the gate electrode 053 may be made of an opaque conductive material. Therefore, as shown in FIG. 4, there is no need to provide a light shielding layer in the display substrate, and an orthographic projection of the gate electrode 053 on the base substrate 00 covers an orthographic projection of the active layer 054 on the base substrate 00, that is, the orthographic projection of the active layer 054 on the base substrate 00 fall within the orthographic projection of the gate electrode 053 on the base substrate 00 or coincides with the orthographic projection of the gate electrode 053 on the base substrate 00, so that gate electrode 053 can effectively block the light incident on the active layer 054.

Continuing to refer to FIG. 2 to FIG. 4, the display substrate may further include an auxiliary electrode 09, and an insulating layer may be formed between the auxiliary electrode 09 and the first capacitor electrode 03. The auxiliary electrode 09 is located in the capacitor region, and is located on a side of the first capacitor electrode 03 close to the base substrate 00, and an orthographic projection of the auxiliary electrode 09 on the base substrate 00 is partly overlapped with an orthographic projection of the first capacitor electrode on the base substrate 00. For example, the orthographic projection of the auxiliary electrode 09 on the base substrate 00 may overlap the orthographic projection of the first capacitor electrode 03 on the base substrate 00, and the orthographic projection of the auxiliary electrode 09 on the base substrate 00 may also overlap an orthographic projection of the second capacitor electrode 04 on the base substrate 00. Alternatively, the orthographic projections of the first capacitor electrode 03 and the second capacitor electrode 04 on the base substrate 00 may both fall within the orthographic projection of the auxiliary electrode 09 on the base substrate 00.

In the embodiments of the present disclosure, the auxiliary electrode 09, the first capacitor electrode 03 and the second capacitor electrode 04 may form a capacitor of a sandwich structure, and the capacitor of the sandwich structure is equivalent to two capacitors connected in parallel, and the capacitance thereof is relative large, thus the charging effect of the pixel electrode can be further ensured, thereby improving the display effect of the display device.

For the display substrate having the thin film transistor with the top gate structure, as shown in FIGS. 2 and 3, the auxiliary electrode 09 may be disposed in the same layer as the light shielding layer 08. In this case, the auxiliary electrode 09 may be formed by one patterning process with the light shielding layer 08, which may simplify the manufacturing process of the display substrate. Correspondingly, as shown in FIG. 2, the insulating layer between the auxiliary electrode 09 and the first capacitor electrode 03 may include the buffer layer 06 and the inter-layer dielectric 07. Alternatively, as shown in FIG. 3, the insulating layer between the auxiliary electrode 09 and the first capacitor electrode 03 may be the buffer layer 06.

For the display substrate having the thin film transistor with the bottom gate structure, as shown in FIG. 4, the auxiliary electrode 09 may be disposed in the same layer as the gate electrode 053. In this case, the auxiliary electrode 09 may be formed by one patterning process with the gate electrode 053, which may simplify the manufacturing process of the display substrate. Correspondingly, as shown in FIG. 4, the insulating layer between the auxiliary electrode 09 and the first capacitor electrode 03 may be the inter-layer dielectric 07.

Optionally, in the embodiments of the present disclosure, the capacitor of the sandwich structure disposed in the display substrate may also be formed by stacking three conductive film layers (i.e. the light shielding layer, the active layer and a source-drain electrode layer) and insulating film layers disposed between each two adjacent conductive film layers, or formed by stacking three conductive film layers (i.e. the active layer, the source-drain electrode layer and an anode layer) and insulating film layers disposed between each two adjacent conductive film layers, which is not limited in the embodiments of the present disclosure.

The display substrate provided by the embodiments of the present disclosure may be applied to an Organic Light-Emitting Diode (OLED) display device, for example, to a white light OLED (WOLED) display device or a full color OLED display device. Moreover, the OLED display device may be a bottom emission display device or a top emission display device.

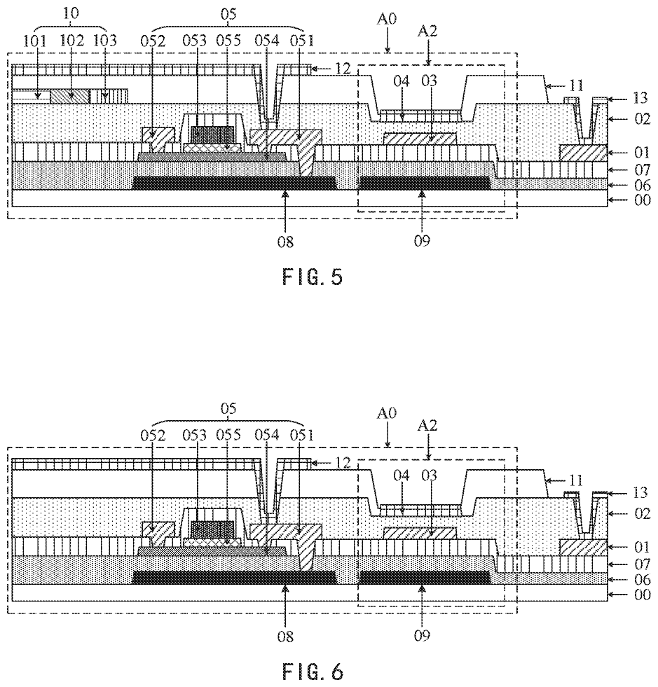

FIG. 5 is a schematic structural view of a bottom emission OLED display device according to some embodiments of the present disclosure. The thin film transistor in the bottom emission OLED display device is a thin film transistor with a bottom gate structure. As shown in FIG. 5, the display substrate may further include:

a color filter layer 10, a planarization layer 11, and an electrode layer which are sequentially disposed on a side of the passivation layer 02 away from the base substrate. The color filter layer 10 is located in the display region. Moreover, the color filter layer 10 may include a plurality of color filter layers of different colors. For example, as shown in FIG. 5, the color filter layer 10 may include a red color filter layer 101, a green color filter layer 102, and a blue color filter layer 103. The electrode layer may include an anode layer 12, the second capacitor electrode 04 located in the capacitor region A2, and a leading wire layer 13 located in the peripheral region. The leading wire layer 13 is electrically connected to the conductive layer 01 through a passivation-layer via hole penetrating the passivation layer 02, and the leading wire layer 13 is used for directly connecting with the driving circuit of the display device, that is, the leading wire layer is a bonding point in the display substrate for bonding with the driving circuit. The anode layer 12 is connected to the source electrode 051 of the thin film transistor 05 through a via hole penetrating the planarization layer 11 and the passivation layer 02.

Further, a light-emitting layer and a cathode layer (not shown in the figure) are sequentially disposed on a side of the anode layer 12 away from the base substrate 00, and the light-emitting layer may emit light under the driving of the anode layer 12 and the cathode layer. Wherein, in order to improve the light extraction efficiency of the bottom emission display device, the cathode layer may be a reflective cathode layer, that is, the cathode layer is made of a material having a reflection effect.

The light-emitting layer may include a plurality of sub light-emitting layers, and the anode layer may include a plurality of anode blocks corresponding to the plurality of sub light-emitting layers. Correspondingly, the display substrate may further include: a pixel defining layer, the pixel defining layer is configured to define a plurality of pixel regions, and one sub light-emitting layer is formed in each of the pixel regions. And an orthographic projection of the pixel defining layer on the base substrate may be partly overlapped with an orthographic projection of the anode layer on the base substrate, for example, the pixel defining layer may cover an edge of each anode block to prevent the burrs on the edge of the anode block from piercing the sub light-emitting layer to form a dark spot defect, thereby ensuring the display effect of the display device.

FIG. 6 is a schematic structural vies of a top emission OLED display device according to some embodiments of the present disclosure. The thin film transistor in the top emission OLED display device is a thin film transistor with a top gate structure. As shown in FIG. 6, the display substrate may further include:

a planarization layer 11 and an electrode layer which are sequentially disposed on a side of the passivation layer 02 away from the base substrate. The electrode layer may include an anode layer 12, a second capacitor electrode 04 located in the capacitor region A2, and a leading wire layer 13 located in the peripheral region. The leading wire layer 13 is electrically connected to the conductive layer 01 through a passivation-layer via hole penetrating the passivation layer 02. The anode layer 12 can be electrically connected to the source electrode 051 of the thin film transistor 05 through a via hole penetrating the planarization layer 11 and the passivation layer 02. Further, a light-emitting layer, a cathode layer and a color filter layer (not shown in the figure) are sequentially disposed on a side of the anode layer 12 away from the base substrate 00. Wherein, in order to improve the light extraction efficiency of the top emission display device, the anode layer 12 may be a reflective anode layer, that is, the anode layer is made of a material having a reflection effect.

Wherein, the anode layer 12, the light-emitting layer, and the cathode layer may constitute a light-emitting unit. As can be seen from FIG. 5 and FIG. 6, in the bottom emission display device, the color filter layer may be located on a side of the light emitting unit close to the base substrate 00. That is, in the bottom emission display device, the base substrate is sequentially provided with an array-arranged thin film transistor, a color filter layer, an anode layer, a light-emitting layer, and a reflective cathode layer. Light emitted by the light-emitting layer is reflected by the reflective cathode layer, then passes through the color filter layer, and is emitted from a bottom of the display substrate (i.e., a side close to the base substrate).

In the top emission display device, the color filter layer may be located on a side of the light emitting unit away from the base substrate 00. That is, in the top emission display device, the base substrate may be sequentially provided with an array-arranged thin film transistor, a reflective anode layer, a light-emitting layer and a cathode layer, and a glass cover plate may be disposed on a side of the cathode layer away from the base substrate. A color filter layer may be disposed on the glass cover plate. Light is emitted from the light-emitting layer, then is reflected by the reflective anode layer to the color filter layer, and finally may be emitted through the glass cover plate.

In summary, the embodiments of the present disclosure provide the display substrate including the conductive layer and the passivation layer which are stacked on the base substrate, and the thickness of the part of the passivation layer in the capacitor region is smaller than that of the part of the passivation layer in the periphery region. Compared with the related art, since the thickness of the part of the passivation layer in the peripheral region is relative large, the compressive property of the passivation layer in the peripheral region may be improved, and since the thickness of the part of the passivation layer in the capacitor region is relative small, the influence of the passivation layer on the capacitance of the storage capacitor may be reduced, and the display effect of the display device may be ensured. Therefore, the passivation layer may meet the requirements of both the compressive property and the capacitance as much as possible.

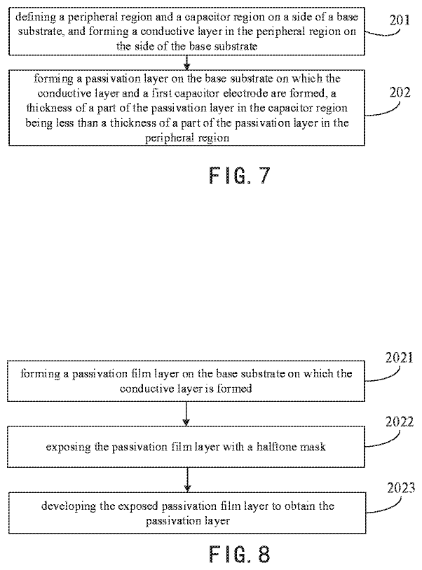

FIG. 7 is a flow chart of a method for manufacturing a display substrate according to some embodiments of the present disclosure, which may be used to manufacture the display substrate shown in any of the above FIG. 1 to FIG. 4. Referring to FIG. 7, the method may include:

Step 201: defining a peripheral region and a capacitor region on a side of a base substrate, and forming a conductive layer in the peripheral region on the side of the base substrate.

The peripheral region may refer to a region around a display region on the base substrate. The capacitor region is a region for setting a capacitor, and the capacitor region is located in the display region. The conductive layer is used for electrical connecting with a driving circuit in a display device.

Step 202: forming a passivation layer on the base substrate on which the conductive layer and a first capacitor electrode are formed, a thickness of a part of the passivation layer in the capacitor region being less than a thickness of a part of the passivation layer in the peripheral region.

In summary, the embodiments of the present disclosure provide the method for manufacturing the display substrate, which may make the thickness of the part of the passivation layer in the capacitor region less than the thickness of the part of the peripheral region when forming the passivation layer in the display substrate. Compared with the related art, since the thickness of the part of the passivation layer in the peripheral region is relative large, the compressive property of the passivation layer in the peripheral region may be improved, and since the thickness of the part of the passivation layer in the capacitor region is relative small, the influence of the passivation layer on the capacitance of the storage capacitor may be reduced, and the display effect of the display device may be ensured. Therefore, the passivation layer may meet the requirements of both the compressive property and the capacitance as much as possible.

FIG. 8 is a flow chart of a method for manufacturing a passivation layer according to some embodiments of the present disclosure. Referring to FIG. 8, the foregoing step 202 may include:

Step 2021: forming a passivation film layer on the base substrate on which the conductive layer is formed.

Optionally, the base substrate is coated with a passivation film material by spin coating, and the passivation film material may be a material such as polysiloxane or polysilazane; after that, the passivation film material may be pre-baked to obtain the passivation film layer.

Step 2022: exposing the passivation film layer with a halftone mask.

During the exposure process, an orthographic projection of a half-exposure region of the halftone mask on the base substrate covers at least an orthographic projection of the capacitor region on the base substrate. For example, the orthographic projection of the half-exposure region of the halftone mask on the base substrate may exactly coincide with the orthographic projection of the capacitor region on the base substrate.

Step 2023: developing the exposed passivation film layer to obtain the passivation layer.

The exposed passivation film layer is developed, so that a part of the material in the passivation film layer corresponding to the half-exposure region is dissolved by developer, so that a thickness of a part of the passivation film layer corresponding to the half-exposure region is thinned. A part of the passivation film layer corresponding to a region other than the half-exposure region does not react with the developer, and thus a thickness of the part of the passivation film layer remains unchanged. After the development is completed, the developed passivation film layer may be post-baked to obtain a passivation layer having a non-uniform thickness, and the thickness of the part of the passivation layer in the capacitor region is less than that of the part of the passivation layer in other regions. The post-baking time of the passivation film layer may be one to two hours.

It should be noted that the light transmittance of the region other than the halftone region in the halftone mark is different depending on the positive and negative sensitivities of the material forming the passivation film layer.

When the material forming the passivation film layer is a positive photosensitive material, the region of the halftone mask other than the half-exposure region may include an opaque region and at least one light transmissive region, and an orthographic projection of the at least one light transmissive region on the base substrate coincides with an orthographic projection of a region, in which via holes are to be formed on the passivation layer, on the base substrate. The via holes may include a via hole in the display region which is used for connecting the source electrode to the anode layer, and a passivation-layer via hole in the peripheral region which is used for connecting the conductive layer to the leading wire layer. Correspondingly, after the exposure, a part of the passivation film layer corresponding to the opaque region is not exposed by ultraviolet light, so that it is not dissolved in the developer during development, and the thickness thereof may be kept unchanged; a part of the passivation film layer corresponding to the half-exposure region is half-exposed, so that it is partially dissolved in the developer during development, and the thickness thereof is reduced; and a part of the passivation film layer corresponding to the light transmissive region is fully exposed, so that it is completely dissolved in the developer during development, and the via holes penetrating the film layer are formed.

When the material forming the passivation film layer is a negative photosensitive material, the region of the halftone mask other than the half-exposure region may include a light transmissive region and at least one opaque region, and an orthographic projection of the at least one opaque region on the base substrate coincides with an orthographic projection of a region, in which via holes are to be formed on the passivation layer, on the base substrate. Correspondingly, after the exposure, a part of the passivation film layer corresponding to the light transmissive region is fully exposed, so that it is not dissolved in the developer during development, and the thickness thereof may be kept unchanged; a part of the passivation film layer corresponding to the half-exposure region is half-exposed, so that it is partially dissolved in the developer during development, and the thickness thereof is reduced; and a part of the passivation film layer corresponding to the opaque region is not exposed, so that it is completely dissolved in the developer during development, and via holes penetrating the film layer are formed.

Optionally, before the step 202, a thin film transistor may be formed in the display region of the base substrate, and a first capacitor electrode is formed in the capacitor region and on a side of the passivation layer close to the base substrate. The conductive layer and the first capacitor electrode may be formed by one patterning process with a source electrode and a drain electrode of the thin film transistor; alternatively, the conductive layer and the first capacitor electrode may also pass through one patterning process with a gate electrode of the thin film transistor.

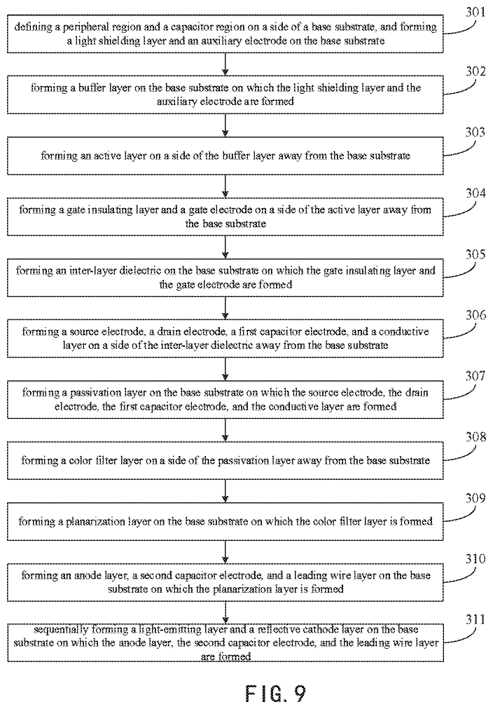

FIG. 9 is a flow chart of another method for manufacturing a display substrate according to some embodiments of the present disclosure. The manufacturing method is described below by taking the display substrate shown in FIG. 5 as an example. Referring to FIG. 9, the method may include:

Step 301: defining a peripheral region and a capacitor region on a side of a base substrate, and forming a light shielding layer and an auxiliary electrode on the base substrate.

The base substrate may be a transparent substrate, such as a transparent glass substrate, and may have a thickness of 50 micrometers (μm) to 1000 μm. When the light shielding layer and the auxiliary electrode are formed, an opaque conductive material may be deposited on the base substrate by using a magnetron sputtering device to obtain a conductive thin film layer, and then the conductive film layer is patterned by a photolithography process and a wet etching process, and then a photoresist is stripped to obtain the light shielding layer and the auxiliary electrode. Wherein, the photolithography process may include: photoresist coating, pre-baking, exposure, development, and post-baking. Moreover, the light shielding layer and the auxiliary electrode may not be formed in one patterning process. For example, the auxiliary electrode may be formed after forming the light shielding layer, or the auxiliary electrode may be formed before forming the light shielding layer.

It should be noted that, before forming the film layers on the base substrate, the display region, the capacitor region, and the peripheral region around the display region may be defined on the side of the base substrate according to design requirements, and the capacitor region is located in the display region, in order to form a corresponding film layer in each region according to design requirements. For example, the auxiliary electrode may be formed in the capacitor region.

Step 302, forming a buffer layer on the base substrate on which the light shielding layer and the auxiliary electrode are formed.

In the embodiments of the present disclosure, the buffer layer may be formed by a method of plasma enhanced chemical vapor deposition (PECVD). The buffer layer may be a single-layer film formed of any one of buffer layer materials such as silicon nitride (SiNx), silicon oxide (SiOx), and silicon oxynitride (SiOxNy), or may be a multilayer film formed by stacking several materials of the above buffer layer materials, each of the layers of the multilayer film is made of one of the several materials. A thickness of the buffer layer may be 150 nanometers (nm) to 500 nm.

Step 303, forming an active layer on a side of the buffer layer away from the base substrate.

Further, an oxide film layer may be deposited on the buffer layer by using a magnetron sputtering device, and then the oxide film layer is patterned by a photolithography process and a wet etching process, and then a photoresist is stripped to obtain the active layer. The oxide film layer may be made of an amorphous oxide material such as indium gallium zinc oxide (IGZO), nitrogen-doped zinc oxide (ZnON), or indium tin zinc oxide (ITZO).

Step 304, forming a gate insulating layer and a gate electrode on a side of the active layer away from the base substrate.

After the active layer is obtained, an insulating material layer may be deposited on the base substrate by chemical vapor deposition (CVD) to obtain an insulating film layer, and then a gate material may be deposited on the insulating film layer by using a magnetron sputtering device to obtain a gate film layer, the gate film layer may have a thickness of 200 nm to 1000 nm, and the material forming the gate film layer may be aluminum (Al), molybdenum (Mo), chromium (Cr), copper (Cu), titanium (Ti) or the like. Thereafter, the gate film layer may be patterned by a photolithography process and a wet etching process to define a pattern of the gate electrode. The insulating film layer is dry etched by using the photoresist on the gate electrode as a mask to obtain the gate insulating layer (GI). Finally, the photoresist is stripped to obtain the gate insulating layer and the gate electrode.

Optionally, in the embodiments of the present disclosure, in order to reduce an ohmic contact resistance between the active layer and the source-drain electrode (i.e., source electrode and drain electrode, SD), a part of the active layer (for example, an IGZO film layer) which is not shielded by the gate insulating layer is subjected to a conductor treatment using any one of ammonia (NH3), nitrogen (N2), and hydrogen (H2), after forming the gate insulating layer.

Step 305, forming an inter-layer dielectric on the base substrate on which the gate insulating layer and the gate electrode are formed.

Further, the inter-layer dielectric (ILD) may be formed by a PECVD method, and the ILD layer may be a single layer film formed of silicon nitride or silicon oxide, or may be a multilayer film formed of the two materials, each layer of the multilayer film is made of one of the two materials. Moreover, after the formation of the ILD layer, a contact via hole for connecting the active layer to a source electrode, and a contact via for connecting the active layer to a drain electrode are formed in the ILD layer by a dry etching process. Further, while forming the contact via holes, a via hole for connecting the source electrode to the light shielding layer may be simultaneously formed.

Step 306, forming a source electrode, a drain electrode, a first capacitor electrode, and a conductive layer on a side of the inter-layer dielectric away from the base substrate.

Further, a metal thin film layer may be deposited on the inter-layer dielectric by using a magnetron sputtering device, the metal thin film layer may have a thickness of 200 nm to 1000 nm, and the metal thin film layer may be formed of a metal material such as Al, Mo, Cr, Cu, or Ti. Thereafter, the metal thin film layer may be patterned by a photolithography process and a wet etching process, and the photoresist is stripped to obtain the source electrode, the drain electrode, the first capacitor electrode located in the capacitor region, and the conductive layer located in the peripheral region, which may be used as a source lead electrode.

Step 307, forming a passivation layer on the base substrate on which the source electrode, the drain electrode, the first capacitor electrode, and the conductive layer are formed.

In the embodiments of the present disclosure, the passivation film layer may be formed by a spin coating method, and the composition of the passivation film layer may be an silicone glass solution. The passivation film layer may then be pre-baked, exposed, and developed to reduce a thickness of a part of the passivation film layer located in the capacitor region such that the thickness of the part of the passivation layer in the capacitor region is less than that of a part of the passivation layer in other regions. For example, the passivation film layer may be exposed using a halftone mask such that the thickness of the part of the passivation film layer in the capacitor region is half of the original thickness after the development process. Further, via holes may be formed in the passivation film layer while the part of the passivation film layer in the capacitor region is thinned by the exposure and development processes. The via holes may include a via hole in the display region which is used for connecting the source electrode to an anode layer, and may further include a passivation-layer via hole in the peripheral region which is used for connecting the conductive layer to a leading wire layer.

After the via holes are formed, the passivation film layer is post-baked in a high temperature environment of 230 degrees Celsius to 250 degrees Celsius, and the post-baking time may be 1 to 2 hours. Due to the presence of an organic functional group on the branch of the silicone material, the organic functional group decomposes to generate gas which escapes under a high temperature post-baking condition, and Si in the SOG material may combine with O to form silicon oxide, so that the passivation film layer becomes a dense silicon oxide (e.g., SiO2) film layer, that is, the passivation layer. The thickness of the part of the passivation layer in the capacitor region may be in a range from 300 nm to 500 nm, and the thickness of the part of the passivation layer in the peripheral region may be in a range from 600 nm to 1000 nm. The process of forming the passivation layer can also refer to the above steps 2021 to 2023, and details are not described herein again.

The passivation layer may resist high temperature, and may effectively prevent water oxygen and metal ions from diffusing into the display substrate. For the thin film transistor with a top gate structure, since the ILD layer blocks water and metal ions from diffusing into the active layer, the organic solvent in the passivation layer has less influence on the thin film transistor in the process of forming the passivation layer.

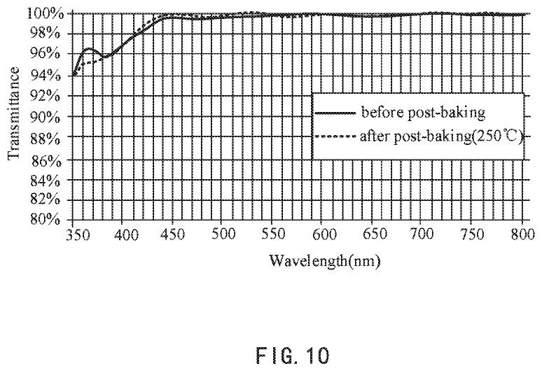

FIG. 10 is a schematic diagram showing the transmittance of a SOG material as a function of a light wavelength, provided by some embodiments of the present disclosure. FIG. 10 shows a change of transmittance of the SOG material before post-baking and that after post-baking, respectively. As can be seen from FIG. 10, the transmittance of the SOG material in a visible light band (i.e., a wavelength band of 380 nm to 780 nm) may be as high as 99.7%, and the transmittance thereof is relative high. Moreover, the SOG material has high UV light stability, low water absorption, low outgassing, good chemical resistance and heat resistance, and is a good substitute for the organic film.

Step 308, forming a color filter layer on a side of the passivation layer away from the base substrate.

A color filter material of one color may be deposited on the passivation layer by a slit coating process, and then pre-baked, exposed and developed, and then post-baked at a high temperature of 230 degrees Celsius to remove water and organic solvent, so as to obtain a color filter layer of the one color. Thereafter, a color filter layer of another color may be produced by the same method, and the color filter layer may have a thickness of 2 um to 3.5 um. As shown in FIG. 5, after the step 308, the formed color filter layer 10 may include a red color filter layer 101, a green color filter layer 102, and a blue color filter layer 103.

Step 309, forming a planarization layer on the base substrate on which the color filter layer is formed.

A planarization material may be deposited on the base substrate on which the color filter layer is formed by using a slit coating process, and then the planarization material is pre-baked, exposed, and developed to obtain a planarization layer having via holes. A bottom of a via hole in the capacitor region may expose the passivation layer in the capacitor region, a bottom of a via hole in the display region may expose a part of the source electrode of the thin film transistor, and a via hole in the peripheral region is connected to the passivation-layer via hole in the peripheral region to expose the conductive layer. Further, after the development is completed, the planarization material may be post-baked at a high temperature of 230 degrees Celsius to remove water and organic solvent in the planarization material so as to obtain the planarization layer. Wherein, the planarization layer may have a thickness of 2 um to 3.5 um.

Step 310, forming an anode layer, a second capacitor electrode, and a leading wire layer on the base substrate on which the planarization layer is formed.

A conductive material may be deposited on the planarization layer by using a magnetron sputtering device to obtain a conductive thin film layer. The conductive material may be a metal material such as Al or Mo, and the conductive thin film layer may have a thickness of 200 nm to 1000 nm. Thereafter, the conductive thin film layer is patterned by a photolithography process and a wet etching process, and the photoresist is stripped to obtain the anode layer and the second capacitor electrode which are located in the display region, and the wiring layer located in the peripheral region. The second capacitor electrode is located in the capacitor region in the display region. Since a portion of the planarization layer in the capacitor region has been removed, the capacitor electrode may directly contact the passivation layer. The anode layer may be connected to the source electrode of the thin film transistor through the via hole in the display region, and the leading wire layer may be connected to the conductive layer through the via hole in the planarization layer and the passivation-layer via hole which are both located in the peripheral region.

In addition, when the display device in which the display substrate is located is a top emission display device, in order to improve the light extraction efficiency of the top emission display device, the anode layer may be a reflective anode layer. In this case, in order to ensure the performance of the anode layer, the anode layer may be made of a conductive material having a high work function and a reflectance higher than 90%.

Step 311, sequentially forming a light-emitting layer and a reflective cathode layer on the base substrate on which the anode layer, the second capacitor electrode, and the leading wire layer are formed.

When the display device in which the display substrate is located is a bottom emission display device, in order to improve the light extraction efficiency of the bottom emission display device, the cathode layer may be a reflective cathode layer. In this case, in order to ensure the performance of the cathode layer, the cathode layer may be made of a conductive material having a high work function and a reflectance higher than 90%.

In summary, the embodiments of the present disclosure provide the method for manufacturing the display substrate, which may make the thickness of the part of the passivation layer in the capacitor region less than the thickness of the part of the peripheral region when forming the passivation layer in the display substrate. Compared with the related art, since the thickness of the part of the passivation layer in the peripheral region is relative large, the compressive property of the passivation layer in the peripheral region may be improved, and since the thickness of the part of the passivation layer in the capacitor region is relative small, the influence of the passivation layer on the capacitance of the storage capacitor may be reduced, and the display effect of the display device may be ensured. Therefore, the passivation layer may meet the requirements of both the compressive property and the capacitance as much as possible.

It should be noted that the sequence of the steps of the method for manufacturing the display substrate provided by the embodiments of the present disclosure may be appropriately adjusted, and the steps may also be correspondingly increased or decreased according to the situation. For example, when the thin film transistor in the display substrate is a transistor with a bottom gate structure, the above step 301 may be selected not to be performed. Accordingly, the auxiliary electrode may be formed with the gate electrode by one patterning process, and step 303 may be performed after step 304; alternatively, when the display substrate is applied to a top emission OLED display device, the above step 308 may be performed after step 310. Any method that can be easily conceived by those skilled in the art within the scope of the technology disclosed in the present disclosure is intended to be included in the scope of the present disclosure, and therefore will not be described again.

Some embodiments of the present disclosure provide a display device, which may include the display substrate as shown in any of FIGS. 1 to 6. The display device may be any product or component having a display function such as an OLED display device, a liquid crystal display device, an electronic paper, a mobile phone, a tablet computer, a television, a display, a notebook computer, a digital photo frame, a navigator, and so on.

The above description is only some embodiments of the present disclosure, and is not intended to limit the disclosure. Any modifications, equivalent substitutions, improvements, etc., made within the spirit and principle of the present disclosure should be included within the scope of the present disclosure.

1. A display substrate comprising: a base substrate, and a conductive layer and a passivation layer which are stacked on the base substrate;
wherein the display substrate has a peripheral region and a capacitor region, the conductive layer is located in the peripheral region, the conductive layer is used for electrically connecting with an external driving circuit, and a thickness of a part of the passivation layer in the capacitor region is less than a thickness of a part of the passivation layer in the peripheral region; and
wherein the capacitor region is provided with a capacitor that charges a pixel unit in the display substrate.

2. The display substrate according to claim 1, wherein the thickness of the part of the passivation layer in the peripheral region is greater than or equal to a reference thickness threshold, and the thickness of the part of the passivation layer in the capacitor region is less than the reference thickness threshold, a passivation layer having a thickness of the reference thickness threshold being capable of withstanding a pressing force during a process of bonding the display substrate and the external driving circuit.

3. The display substrate according to claim 1, wherein the thickness of the part of the passivation layer in the capacitor region is half of the thickness of the part of the passivation layer in the peripheral region.

4. The display substrate according to claim 1, wherein the thickness of the part of the passivation layer in the peripheral region is in a range of 600-1000 nm, and the thickness of the part of the passivation layer in the capacitor region is in a range of 300-500 nm.

5. The display substrate according to claim 1, wherein an orthographic projection of the passivation layer on the base substrate substantially covers the base substrate, and the thickness of the part of the passivation layer in the capacitor region is less than a thickness of a part of the passivation layer in other regions than the capacitor region.

6. The display substrate according to claim 5, wherein the passivation layer has the same thickness in the other regions.

7. The display substrate according to claim 1, further comprising:
a thin film transistor between the base substrate and the passivation layer, wherein the thin film transistor is located in a display region which is surrounded by the peripheral region, and the capacitor region is located in the display region;
wherein the thin film transistor comprises a source electrode, and the conductive layer is electrically connected to the source electrode.

8. The display substrate according to claim 1, further comprising:
a thin film transistor between the base substrate and the passivation layer, wherein the thin film transistor is located in a display region which is surrounded by the peripheral region, and the capacitor region is located in the display region;
wherein the thin film transistor comprises a gate electrode, and the conductive layer is electrically connected to the gate electrode.

9. The display substrate according to claim 7, wherein the thin film transistor is a thin film transistor with a top gate structure; and
wherein the display substrate further comprises a light shielding layer between the base substrate and the thin film transistor, the thin film transistor comprises an active layer, and an orthographic projection of the light shielding layer on the base substrate covers an orthographic projection of the active layer on the base substrate.

10. The display substrate according to claim 7, wherein the thin film transistor is a thin film transistor with a bottom gate structure; and
wherein the thin film transistor comprises a gate electrode and an active layer, and an orthographic projection of the gate electrode on the base substrate covers an orthographic projection of the active layer on the base substrate.

11. The display substrate according to claim 1, further comprising:
a first capacitor electrode on a side of the passivation layer adjacent to the base substrate; and
a second capacitor electrode on a side of the passivation layer away from the base substrate,
wherein the first capacitor electrode and the second capacitor electrode are both located in the capacitor region, and the capacitor comprises the first capacitor electrode and the second capacitor electrode.

12. The display substrate according to claim 1, further comprising a leading wire layer, wherein the leading wire layer is electrically connected to the conductive layer through a passivation-layer via hole penetrating the passivation layer.

13. A display substrate according to claim 1, wherein the passivation layer is made of one of polysiloxane or polysilazane.

14. The display substrate according to claim 1, wherein the display substrate has a display region surrounded by the peripheral region, the display region comprises the capacitor region, and the display substrate further comprises: a light shielding layer, a thin film transistor with a top gate structure, a first capacitor electrode a planarization layer, an electrode layer, a light-emitting layer, a cathode layer, and a color filter layer which are disposed on the base substrate; wherein:
the light shielding layer and the thin film transistor are located in the display region, and an orthographic projection of the light shielding layer on the base substrate covers an orthographic projection of an active layer in the thin film transistor on the base substrate;
the electrode layer comprises a second capacitor electrode, the first capacitor electrode and the second capacitor electrode are located in the capacitor region, and the capacitor comprises the first capacitor electrode and the second capacitor electrode;
the conductive layer is further used for electrically connecting with one of a source electrode or a gate electrode of the thin film transistor;
an orthographic projection of the passivation layer on the base substrate substantially covers the base substrate, and the thickness of the part of the passivation layer in the capacitor region is equal to half of a thickness of a part of the passivation layer in other regions than the capacitor region, and the passivation layer has the same thickness in the other regions, the passivation layer being made of one of polysiloxane or polysilazane; and
the electrode layer further comprises a reflective anode layer, and a leading wire layer located in the peripheral region, the leading wire layer is electrically connected to the conductive layer through a passivation-layer via hole penetrating the passivation layer, and the reflective anode layer is electrically connected to the source electrode through a via hole penetrating both the planarization layer and the passivation layer.

15. The display substrate according to claim 1, wherein the capacitor region is located in the display region surrounded by the peripheral region, and the display substrate further comprises: a thin film transistor with a bottom gate structure, a first capacitor electrode a color filter layer, a planarization layer, an electrode layer, a light-emitting layer, and a reflective cathode layer which are disposed on the base substrate; wherein:
the thin film transistor is located in the display region, and an orthographic projection of a gate electrode of the thin film transistor on the base substrate covers an orthographic projection of an active layer of the thin film transistor on the base substrate;
the electrode layer comprises a second capacitor electrode, the first capacitor electrode and the second capacitor electrode are located in the capacitor region, and the capacitor comprises the first capacitor electrode and the second capacitor electrode;
the conductive layer is further used for electrically connecting with one of a source electrode and the gate electrode of the thin film transistor;
an orthographic projection of the passivation layer on the base substrate substantially covers the base substrate, and the thickness of the part of the passivation layer in the capacitor region is equal to half of a thickness of a part of the passivation layer in other regions than the capacitor region, and the passivation layer has the same thickness in the other regions, the passivation layer being made of one of polysiloxane or polysilazane;
the electrode layer further comprises an anode layer and a leading wire layer located in a peripheral region, the leading wire layer is electrically connected to the conductive layer through a passivation-layer via hole penetrating the passivation layer, and the anode layer is electrically connected to the source electrode through a via hole penetrating both the planarization layer and the passivation layer.

16. A method for manufacturing a display substrate, the method comprising:
defining a peripheral region and a capacitor region on a side of a base substrate;
forming a conductive layer in the peripheral region on the side of the base substrate, the conductive layer being used for electrically connecting with an external driving circuit; and
forming a passivation layer on the base substrate on which the conductive layer is formed, a thickness of a part of the passivation layer in the capacitor region being less than a thickness of a part of the passivation layer in the peripheral region;
wherein the capacitor region is used to form a capacitor that charges a pixel unit in the display substrate.

17. The method according to claim 16, wherein the forming the passivation layer on the base substrate on which the conductive layer is formed comprises:
forming a passivation film layer on the base substrate on which the conductive layer is formed;
exposing the passivation film layer with a halftone mask, wherein an orthographic projection of a half-exposure region of the halftone mask on the base substrate at least covers an orthographic projection of the capacitor region on the base substrate during a exposure process; and
developing the exposed passivation film layer to obtain the passivation layer.

18. The method according to claim 17, wherein a passivation-layer via hole penetrating the passivation layer is provided in the passivation layer; and wherein:
a material forming the passivation film layer is a positive photosensitive material, a region of the halftone mask except the half-exposure region comprises an opaque region and at least one light transmissive region, and an orthographic projection of the at least one light transmissive region on the base substrate coincides with an orthographic projection of the passivation-layer via hole on the base substrate; or
a material forming the passivation film layer is a negative photosensitive material, a region of the halftone mask except the half-exposure region comprises a light transmissive region and at least one opaque region, and an orthographic projection of the at least one opaque region on the base substrate coincides with an orthographic projection of the passivation-layer via hole on the base substrate.

19. The method according to claim 16, wherein prior to forming the passivation layer, the method further comprises:
forming a thin film transistor in a display region surrounded by the peripheral region on the side of the base substrate, the capacitor region being located in the display region; and
forming a first capacitor electrode of the capacitor in the capacitor region on the side of the base substrate,
wherein the conductive layer and the first capacitor electrode satisfy any one of the following:
the conductive layer and the first capacitor electrode are formed by one same patterning process as a source electrode and a drain electrode of the thin film transistor; or
the conductive layer and the first capacitor electrode are formed by one same patterning process as a gate electrode of the thin film transistor.

20. A display device comprising: the display substrate according to claim 1.
